(19) United States
(12) Patent Application Publication
(10) Pub. No.: US 2022/0201874 A1
(43) Pub. Date: Jun. 23, 2022

(54) FOLDABLE DISPLAY DEVICE

(71) Applicant: SAMSUNG DISPLAY CO., LTD., YONGIN-SI (KR)

(72) Inventors: JUNGHWA YOU, Hwaseong-si (KR); ALEXANDER VORONOV, Suwon-si (KR); HYUNGSIK KIM, Suwon-si (KR); JOONGSUNG LEE, Hwaseong-si (KR); JEKIL RYU, Suwon-si (KR); SUNGGYU PARK, Hwaseong-si (KR); WOOHYUN JUNG, Seoul (KR); GYOOWAN HAN, Yongin-si (KR)

(21) Appl. No.: 17/536,160

(22) Filed: Nov. 29, 2021

(30) Foreign Application Priority Data
Dec. 23, 2020 (KR) 10-2020-0182157

(51) Int. Cl. H05K 5/00

(52) U.S. Cl. CPC H05K 5/0017

(57) ABSTRACT

A foldable display device including: a flexible display module including a first area, a second area, and a foldable area between the first area and the second area; a first support part disposed under the flexible display module, and including a plurality of first carbon fibers extending in a first direction; and a second support part disposed under the first support part, and including a plurality of second carbon fibers extending in a second direction.

### CROSS-REFERENCE TO RELATED APPLICATION

This application claims priority under 35 U.S.C. § 119 to Korean Patent Application No. 10-2020-0182157 filed on Dec. 23, 2020 in the Korean Intellectual Property Office (KIPO), the disclosure of which is incorporated by reference herein in its entirety.

### 1. TECHNICAL FIELD

The present invention relates to a foldable display device. More particularly, the present invention relates to a foldable display device including a support part.

### 2. DESCRIPTION OF THE RELATED ART

A display device is an output device for presentation of information in visual form. For example, the display device may display an image to provide information to a user. A flexible display device is an electronic visual display that is flexible in nature, as opposed to traditional flat screen displays. For example, the flexible display device may include a part that is bent and display an image in the bent part.

Recently, a foldable display device has been developed. The foldable display device may be repeatedly folded or unfolded. The foldable display device may include a flexible display module, and a support part disposed on a bottom surface of the flexible display module. The support part may have relatively high rigidity to prevent the flexible display module from being deformed by a touch of the user or the like.

In general, a metal has been used to form the support part. However, when the support part includes the metal, a weight of the foldable display device may be increased. In addition, when the foldable display device is repeatedly folded and unfolded, creases may be formed on the support part due to its metal composition.

### SUMMARY

Embodiments of the present invention provide a foldable display device including a support part.

A foldable display device according to an embodiment of the present invention may include: a flexible display module including a first area, a second area, and a foldable area between the first area and the second area; a first support part disposed under the flexible display module, and including a plurality of first carbon fibers extending in a first direction; and a second support part disposed under the first support part, and including a plurality of second carbon fibers extending in a second direction.

The first direction and the second direction may be different from each other.

The flexible display module may be foldable along a folding axis in the folding area, and the first direction and the second direction may be symmetrical to each other based on the folding axis.

The flexible display module may be foldable along a folding axis in the folding area, and the first direction and the second direction may be perpendicular to each other.

The first direction may be parallel to the folding axis.

The first direction may be perpendicular to the folding axis.

The foldable display device may further include a third support part disposed under the second support part, and including a plurality of third carbon fibers extending in a third direction.

The third direction may be identical to the first direction.

The flexible display module may be foldable about a folding axis in the folding area, the first direction and the second direction may be symmetrical with each other based on the folding axis, and the first direction and the second direction may be perpendicular to each other.

Each of the first support part and the second support part may include carbon fiber-reinforced plastic (CFRP).

Each of the first support part and the second support part may further include a plurality of grooves in the foldable area.

The foldable display device may further include: a first plate disposed under the second support part, and overlapping the first area; and a second plate disposed under the second support part, overlapping the second area, and spaced apart from the first plate.

Each of the first plate and the second plate may partially overlap the foldable area.

Each of the first plate and the second plate may include CFRP.

A foldable display device according to an embodiment of the present invention may include: a flexible display module including a first area, a second area, and a foldable area between the first area and the second area; a first support part disposed under the flexible display module, and including a plurality of first carbon fibers extending in a first direction; a second support part disposed under the first support part; and a third support part under the second support part, and including a plurality of second carbon fibers extending in a second direction.

The first direction may be identical to the second direction.

The first direction may be different from the second direction.

The flexible display module may be foldable about a folding axis in the folding area, and the first direction and the second direction may be symmetrical with each other based on the folding axis.

The first direction and the second direction may be perpendicular to each other.

The second support part may not include carbon fibers.

A foldable display device according to an embodiment of the present invention may include: a flexible display module including a first area, a second area, and a foldable area between the first area and the second area; a first support part disposed under the flexible display module; and a second support part disposed under the first support part, wherein at least one of the first support part and the second support part includes carbon fibers.

At least one of the first support part and the second support part may include a groove in the folding area.

The foldable display device may further include a first plate disposed on the second support part in the first area and a second plate disposed on the second support part in the second area, wherein the first plate and the second plate are separated from each other in the folding area.

According to the embodiments of the present invention, the foldable display device may include a support part including a plurality of carbon fibers. Accordingly, a weight of the foldable display device may be decreased, and creases generated when the foldable display device is folded or unfolded may be reduced.

### BRIEF DESCRIPTION OF THE DRAWINGS

FIG. 1 is a perspective view showing an unfolded state of a flexible display module included in a foldable display device according to an embodiment of the present invention.

FIG. 2 is a sectional view showing a folded state of the flexible display module of FIG. 1.

FIG. 3 is a sectional view showing a foldable display device according to an embodiment of the present invention.

FIG. 4 is an enlarged sectional view showing region ‘A’ of FIG. 3.

FIG. 5 is a perspective view showing support parts included in the foldable display device of FIG. 3.

FIG. 6 is a plan view showing a foldable display device according to an embodiment of the present invention.

FIG. 7 is a perspective view showing support parts included in the foldable display device of FIG. 6.

FIG. 8 is a plan view showing a foldable display device according to an embodiment of the present invention.

FIG. 9 is a perspective view showing support parts included in the foldable display device of FIG. 8.

FIG. 10 is a plan view showing a foldable display device according to an embodiment of the present invention.

FIG. 11 is a perspective view showing support parts included in the foldable display device of FIG. 10.

FIG. 12 is a sectional view showing a foldable display device according to an embodiment of the present invention.

FIG. 13 is a perspective view showing support parts included in the foldable display device of FIG. 12.

FIGS. 14, 15 and 16 are sectional views showing foldable display devices according to embodiments of the present invention.

FIG. 17 is a sectional view showing a foldable display device according to an embodiment of the present invention.

FIGS. 18 and 19 are perspective views showing support parts included in the foldable display device of FIG. 17.

### DETAILED DESCRIPTION OF THE EMBODIMENTS

Hereinafter, a foldable display device according to embodiments of the present invention will be described in more detail with reference to the accompanying drawings. The same or similar reference numerals may be used for the same elements in the accompanying drawings.

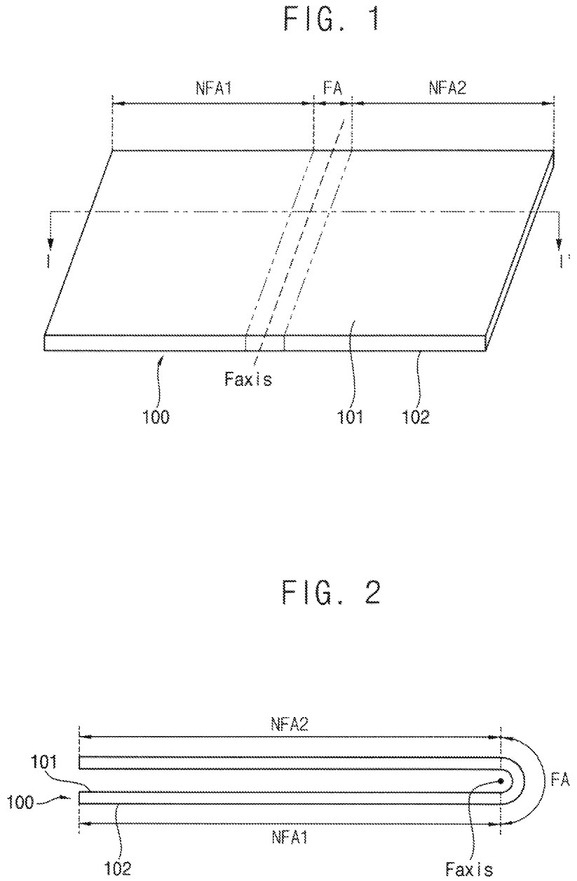

FIG. 1 is a perspective view showing an unfolded state of a flexible display module included in a foldable display device according to an embodiment of the present invention. FIG. 2 is a sectional view showing a folded state of the flexible display module of FIG. 1.

FIGS. 1 and 2 show a flexible display module 100 included in a foldable display device according to embodiments of the present invention. It is to be understood, however, that the flexible display module 100 may be applied to a display device included in a laptop computer, a mobile phone, a smartphone, a smart pad, a portable media player (PMP), a personal digital assistant (PDA), and the like.

The flexible display module 100 may include a first surface 101 and a second surface 102 opposite to the first surface 101. The first surface 101 may be a surface on which an image is displayed in the flexible display module 100. The second surface 102 may be a surface on which an image is not displayed in the flexible display module 100. In an embodiment of the present invention, an image may also be displayed on the second surface 102. For example, an image may be displayed on a part of the second surface 102. Alternatively, an image may be displayed on an entire area of the second surface 102.

The flexible display module 100 may have a stacked structure. For example, the flexible display module 100 may include a plurality of layers having mutually different functions. Each of the layers may have a flexible characteristic, so that the flexible display module 100 may have a flexible characteristic.

The flexible display module 100 may include a first area NFA1, a second area NFA2 spaced apart from the first area NFA1, and a foldable area FA positioned between the first area NFA1 and the second area NFA2. In FIG. 1 of the first area NFA1 and the second area NFA2 are disposed adjacent to short sides of the flexible display module 100. Alternatively, the first area NFA1 and the second area NFA2 may be disposed adjacent to long sides of the flexible display module 100.

The flexible display module 100 may not be folded in the first and second areas NFA1 and NFA2. In other words, the first and second areas NFA1 and NFA2 may not have flexible characteristics. The flexible display module 100 may have a flat surface in the first and second areas NFA1 and NFA2.

The flexible display module 100 may be folded or unfolded in the foldable area FA. For example, the flexible display module 100 may have a folding axis Faxis on the first surface 101 in the foldable area FA. The flexible display module 100 may be folded (e.g., the folded state of FIG. 2) or unfolded (e.g., the unfolded state of FIG. 1) in the foldable area FA based on the folding axis Faxis. In other words, the flexible display module 100 is foldable or unfoldable about the folding axis Faxis. As shown in FIG. 2, when the flexible display module 100 is folded, the first and second areas NFA1 and NFA2 may overlap each other.

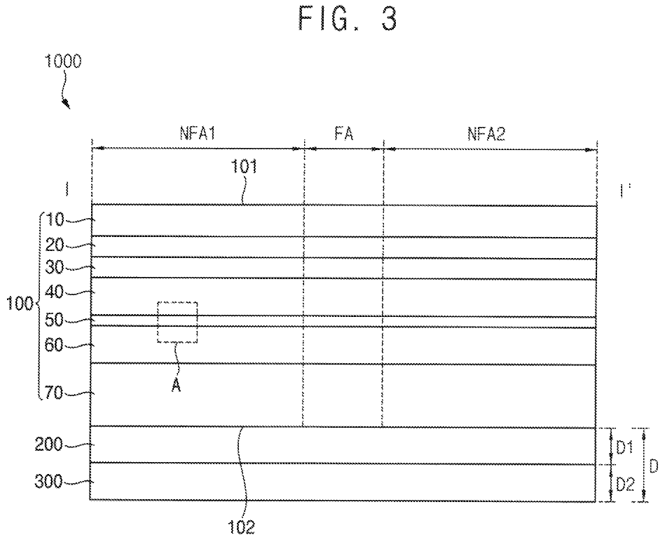

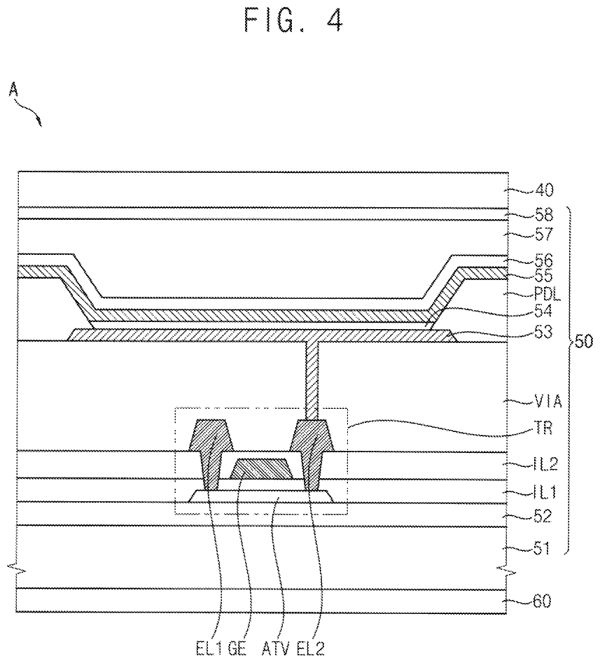

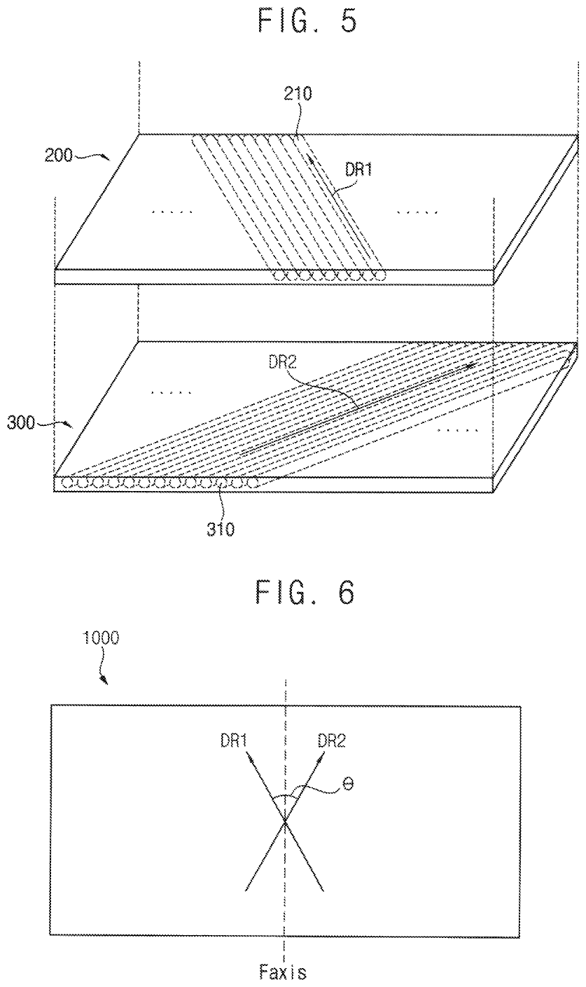

FIG. 3 is a sectional view showing a foldable display device according to an embodiment of the present invention. FIG. 4 is an enlarged sectional view showing region ‘A’ of FIG. 3. FIG. 5 is a perspective view showing support parts included in the foldable display device of FIG. 3.

The flexible display module 100 shown in FIG. 3 may correspond to a sectional view showing the flexible display module 100 of FIG. 1 taken along line I-I′. The flexible display module 100 may include a window protection layer 10, a window 20, a polarizing layer 30, a sensing layer 40, a display panel 50, a protective film 60, and a buffer member 70. The window protection layer 10, the window 20, the polarizing layer 30, the sensing layer 40, the display panel 50, the protective film 60, and the buffer member 70 may be stacked in sequence with the window protection layer 10 adjacent to the first surface 101 of the flexible display module 100 and the buffer member 70 adjacent to the second surface 102 of the flexible display module 100. Since the flexible display module 100 may be folded or unfolded, each of the window protection layer 10, the window 20, the polarizing layer 30, the sensing layer 40, the display panel 50, the protective film 60, and the buffer member 70 may have a flexible characteristic.

The window protection layer 10 may protect the window 20. The window 20 included in a foldable display device 1000 may have flexibility. In this case, the window 20 may be vulnerable to an external force. For example, a shape of the window 20 may be deformed by the external force such as a denting force, or the window 20 may be abraded by a repetitive touch of a user or the like. The window protection layer 10 may prevent the window 20 from being deformed or abraded by the external force.

The window protection layer 10 may include a flexible layer and a rigid layer, which are sequentially stacked. The flexible layer may include polyurethane (PU), thermoplastic polyurethane (TPU), silicon (Si), poly dimethyl acrylamide (PDMA), and the like. The rigid layer may include a silicone resin and a metal oxide. The silicone resin may be silsesquioxane (SSQ) such as hydrogen silsesquioxane (HSQ) and methyl silsesquioxane (MSQ). In addition, the metal oxide may include aluminum oxide (Al₂O₃), silicon dioxide (SiO₂), indium tin oxide (ITO), fluorine-doped tin oxide (FTO), antimony tin oxide (ATO), aluminum zinc oxide (AZO), and the like.

The window 20 may be disposed on a bottom surface of the window protection layer 10. The window 20 may protect the sensing layer 40 and the display panel 50 from an external impact. The window 20 may include colorless polyimide, ultra-thin tempered glass (UTG), polyethylene terephthalate (PET), polyimide (PI), polyethersulfone (PES), polyacrylate (PAR), polyetherimide (PEI), polyethylene naphthalate (PEN), polyphenylene sulfide (PPS), polycarbonate (PC), and the like.

The polarizing layer 30 may be disposed on a bottom surface of the window 20. The polarizing layer 30 may reduce reflection of an external light from the foldable display device 1000. For example, when the external light passes through the polarizing layer 30, is reflected from beneath the polarizing layer 30 (e.g., the display panel 50), and passes through the polarizing layer 30 again, a phase of the external light may be changed by passing through the polarizing layer 30 twice. Accordingly, since a phase of the reflected light is different from a phase of an incident light that enters the polarizing layer 30, destructive interference may occur, and thus, the reflection of the external light may be reduced, so that the visibility of the foldable display device 1000 may be improved.

The sensing layer 40 may be disposed on a bottom surface of the polarizing layer 30. The sensing layer 40 may sense an external input such as contact or approach of an external object to the foldable display device 1000. For example, the sensing layer 40 may sense the external input in a capacitive scheme. In some embodiments of the present invention, the sensing layer 40 may be disposed on the polarizing layer 30. For example, the sensing layer 40 may be provided between the polarizing layer 30 and the window 20.

The display panel 50 may be disposed on a bottom surface of the sensing layer 40. The display panel 50 may include a plurality of pixels, and may generate an image by combining lights emitted from the pixels, respectively.

The protective film 60 may be disposed on a bottom surface of the display panel 50. The protective film 60 may prevent moisture and oxygen from penetrating from outside the foldable display device 1000, and may absorb an external impact.

The buffer member 70 may be disposed on a bottom surface of the protective film 60. The buffer member 70 may buffer an external impact to protect the display panel 50. For example, the buffer member 70 may include a material containing air to perform buffering, such as a cushion and a sponge. In addition, the buffer member 70 may include an acryl-based resin, polyurethane, thermoplastic polyurethane, latex, polyurethane foam, polystyrene foam, and the like.

Although the embodiment in which the flexible display module 100 includes the window protection layer 10, the window 20, the polarizing layer 30, the sensing layer 40, the display panel 50, the protective film 60, and the buffer member 70 has been described above, the flexible display module 100 is not limited to the above-described structure. For example, the flexible display module 100 may include any structure with flexibility that is capable of emitting a light to display an image.

Referring to FIG. 4, the display panel 50 may include a substrate 51, a buffer layer 52, a first insulating layer IL1, a second insulating layer IL2, a transistor TR, a via insulating layer VIA, a pixel electrode 53, a light emitting layer 54, a common electrode 55, a pixel defining layer PDL, a first inorganic layer 56, an organic layer 57, and a second inorganic layer 58. The second inorganic layer 58 may be disposed adjacent to the sensing layer 40 and the substrate 51 may be disposed adjacent to the protective film 60. The transistor TR may include a first electrode EL1, a second electrode EL2, an active pattern ATV, and a gate electrode GE.

The substrate 51 may include glass, quartz, plastic, and the like. For example, the substrate 51 may be a plastic substrate, and may include polyimide (PI). In an embodiment of the present invention, the substrate 51 may have a structure in which at least one polyimide layer and at least one barrier layer are alternately stacked.

The buffer layer 52 may be disposed on the substrate 51. The buffer layer 52 may include silicon oxide, silicon nitride, and the like. The buffer layer 52 may prevent impurities from diffusing from a bottom surface of the buffer layer 52 to the active pattern ATV.

The active pattern ATV may be disposed on the buffer layer 52. The active pattern ATV may include a silicon semiconductor, an oxide semiconductor, and the like. The silicon semiconductor may include amorphous silicon, polycrystalline silicon, and the like. The active pattern ATV may allow a current to pass therethrough or block the current according to a gate signal provided to the gate electrode GE. For example, if the gate signal provided to the gate electrode GE turns on the transistor TR, the current may pass through the active pattern ATV.

The first insulating layer IL1 may include an insulating material, and may cover the active pattern ATV. For example, the first insulating layer IL1 may include silicon oxide, silicon nitride, titanium oxide, tantalum oxide, and the like. The first insulating layer IL1 may electrically insulate the active pattern ATV and the gate electrode GE from each other.

The gate electrode GE may include a metal, an alloy, conductive metal oxide, and the like, and may be disposed on the first insulating layer IL1. For example, the gate electrode GE may include silver (Ag), a silver-containing alloy, molybdenum (Mo), a molybdenum-containing alloy, aluminum (Al), an aluminum-containing alloy, aluminum nitride (AlNₓ), tungsten (W), tungsten nitride (WNₓ), copper (Cu), nickel (Ni), chromium (Cr), chromium nitride (CrNₓ), titanium (Ti), tantalum (Ta), platinum (Pt), scandium (Sc), indium tin oxide (ITO), indium zinc oxide (IZO), and the like.

The second insulating layer IL2 may include an insulating material, and may cover the gate electrode GE. For example, the second insulating layer IL2 may include silicon oxide, silicon nitride, titanium oxide, tantalum oxide, and the like. The second insulating layer IL2 may electrically insulate the gate electrode GE from the first electrode EL1, and may electrically insulate the gate electrode GE from the second electrode EL2.

Each of the first electrode EL1 and the second electrode EL2 may include a metal, an alloy, conductive metal oxide, and the like, and may be disposed on the second insulating layer IL2. For example, each of the first and second electrodes EL1 and EL2 may include silver (Ag), a silver-containing alloy, molybdenum (Mo), a molybdenum-containing alloy, aluminum (Al), an aluminum-containing alloy, aluminum nitride (AlNₓ), tungsten (W), tungsten nitride (WNₓ), copper (Cu), nickel (Ni), chromium (Cr), chromium nitride (CrNₓ), titanium (Ti), tantalum (Ta), platinum (Pt), scandium (Sc), indium tin oxide (ITO), indium zinc oxide (IZO), and the like. One of the first electrode EL1 and second electrode EL2 may serve as a source electrode of transistor TR and the other may serve as a drain electrode of the transistor TR.

The via insulating layer VIA may cover the first and second electrodes EL1 and EL2, may include an organic insulating material, and may have a substantially flat top surface. For example, the via insulating layer VIA may include a photoresist, a polyacryl-based resin, a polyimide-based resin, an acryl-based resin, and the like.

The pixel electrode 53 may be disposed on the via insulating layer VIA. The pixel electrode 53 may include a metal, an alloy, conductive metal oxide, and the like. For example, the pixel electrode 53 may include silver (Ag), a silver-containing alloy, molybdenum (Mo), a molybdenum-containing alloy, aluminum (Al), an aluminum-containing alloy, aluminum nitride (AlNₓ), tungsten (W), tungsten nitride (WNₓ), copper (Cu), nickel (Ni), chromium (Cr), chromium nitride (CrNₓ), titanium (Ti), tantalum (Ta), platinum (Pt), scandium (Sc), indium tin oxide (ITO), indium zinc oxide (IZO), and the like. The pixel electrode 53 may receive a first voltage from the second electrode EL2. For example, the pixel electrode 53 may receive a pixel voltage.

The pixel defining layer PDL may be disposed on the via insulating layer VIA, and include an opening that exposes a top surface of the pixel electrode 53. The pixel defining layer PDL may include an organic material such as a polyimide-based resin (e.g., a photosensitive polyimide (PSPI)-based resin), a photoresist, a polyacryl-based resin, and an acryl-based resin, or an inorganic material such as silicon oxide and silicon nitride.

The light emitting layer 54 may be disposed on the pixel electrode 53. For example, the light emitting layer 54 may be disposed on the pixel electrode 53 exposed in the opening of the pixel defining layer PDL. The light emitting layer 54 may have a multilayer structure including an organic emission layer, a hole injection layer, a hole transport layer, an electron transport layer, and an electron injection layer.

The common electrode 55 may be disposed on the light emitting layer 54, and may receive a second voltage. For example, the common electrode 55 may receive a common voltage. The common electrode 55 may include a metal, an alloy, conductive metal oxide, and the like. For example, the common electrode 55 may include silver (Ag), a silver-containing alloy, molybdenum (Mo), a molybdenum-containing alloy, aluminum (Al), an aluminum-containing alloy, aluminum nitride (AlNₓ), tungsten (W), tungsten nitride (WNₓ), copper (Cu), nickel (Ni), chromium (Cr), chromium nitride (CrNₓ), titanium (Ti), tantalum (Ta), platinum (Pt), scandium (Sc), indium tin oxide (ITO), indium zinc oxide (IZO), and the like.

The light emitting layer 54 may generate a light caused by a voltage difference between the first voltage and the second voltage. Accordingly, the pixel electrode 53, the light emitting layer 54, and the common electrode 55 may be an organic light emitting diode.

A thin film encapsulation layer may be disposed on the common electrode 55. The thin film encapsulation layer may prevent moisture and oxygen from penetrating from the outside of the foldable display device 1000. For example, the thin film encapsulation layer may have a structure in which the first inorganic layer 56, the organic layer 57, and the second inorganic layer 58 are alternately stacked.

Although the embodiment in which the display panel 50 includes the organic emission layer has been described above, the display panel 50 is not limited to the above-described embodiment. The display panel 50 may include any structure capable of receiving an electrical signal to emit a light having a luminance corresponding to an intensity of the electrical signal. For example, the light emitting layer 54 may include quantum dots (QD). As another example, a color filter including the quantum dots may be disposed on the thin film encapsulation layer of the display panel 50.

Referring to FIGS. 3 and 5, a first support part 200 may be disposed on a bottom surface of the flexible display module 100. For example, the first support part 200 may be disposed under the buffer member 70. In addition, the first support part 200 may be provided in the first area NFA1, the second area NFA2, and the foldable area FA. The first support part 200 may support the flexible display module 100. For example, rigidity of the first support part 200 may be greater than rigidity of the flexible display module 100. In this case, the first support part 200 may prevent the flexible display module 100 from being deformed by an external force of the user or the like. The first support part 200 may include a plurality of first carbon fibers 210 extending in a first direction DR1. The first direction DR1 may be slanted with respect to the long sides of the first support part 200.

The second support part 300 may be disposed on a bottom surface of the first support part 200. For example, the second support part 300 may be in direct contact with the first support part 200. The second support part 300 may support the flexible display module 100. For example, rigidity of the second support part 300 may be greater than the rigidity of the flexible display module 100. In this case, the second support part 300 may prevent the flexible display module 100 from being deformed by an external force of the user or the like. The second support part 300 may include a plurality of second carbon fibers 310 extending in a second direction DR2. The second direction DR2 may be slanted with respect to long sides of the second support part 300. The first direction DR1 and the second direction DR2 may be different from each other. For example, the first direction DR1 and the second direction DR2 may be perpendicular to each other. Alternatively, the first direction DR1 may be diagonal with respect to the long sides of the first support part 200 and the second direction DR2 may be parallel to the long sides of the second support part 300.

The first support part 200 may have a first thickness D1, and the second support part 300 may have a second thickness D2. In an embodiment of the present invention, a sum D of the first thickness D1 and the second thickness D2 may be approximately 80 μm or more and approximately 200 μm or less.

According to the foldable display device 1000 of an embodiment of the present invention, the first support part 200 may include the first carbon fibers 210 extending in the first direction DR1, and the second support part 300 may include the second carbon fibers 310 extending in the second direction DR2 that is different from the first direction DR1. Accordingly, the first and second support parts 200 and 300 may have rigidity that is higher than rigidity of a metal support part having a thickness equal to the sum of the first thickness D1 and the second thickness D2. In addition, the first and second support parts 200 and 300 may have a weight that is lower than a weight of the metal support part. Since the first and second support parts 200 and 300 include the first and second carbon fibers 210 and 310, respectively, the first and second support parts 200 and 300 may have a black color. Therefore, the first and second support parts 200 and 300 may not be visually recognized by the user who uses the foldable display device 1000. In addition, since the first and second support parts 200 and 300 include the first and second carbon fibers 210 and 310, respectively, even when the foldable display device 1000 is repeatedly folded and unfolded, creases may not be formed on the first and second support parts 200 and 300.

In an embodiment of the present invention, each of the first support part 200 and the second support part 300 may include carbon fiber-reinforced plastic (CFRP). The CFRP may include a plurality of carbon fibers extending in one direction, and a binding polymer configured to fix the carbon fibers. The binding polymer may include an epoxy resin that is a thermosetting resin.

A foldable display device 1000 according to an embodiment of the present invention includes: a flexible display module 100 including a first area NFA1, a second area NFA2, and a foldable area FA between the first area NFA1 and the second area NFA2; a first support part 200 disposed on the flexible display module 100, and including a plurality of first carbon fibers 210 extending in a first direction DR1; and a second support part 300 disposed on the first support part 200, and including a plurality of second carbon fibers 310 extending in a second direction DR2, wherein the first support part 200 is disposed between the flexible display module 100 and the second support part 200.

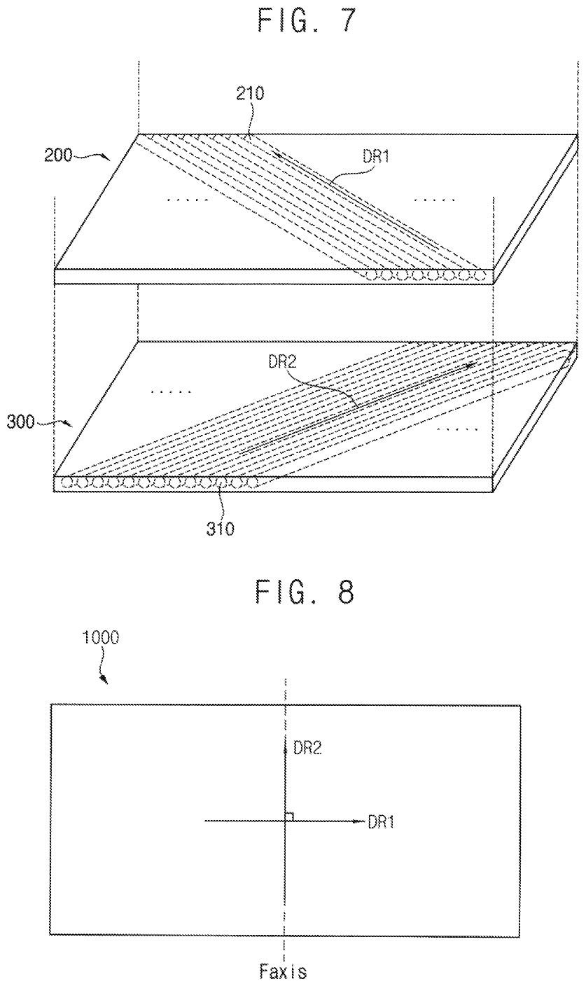

FIG. 6 is a plan view showing a foldable display device according to an embodiment of the present invention. FIG. 7 is a perspective view showing support parts included in the foldable display device of FIG. 6.

Referring to FIGS. 6 and 7, the first direction DR1 and the second direction DR2 may be symmetrical with each other based on the folding axis Faxis. In this case, an angle formed by the first direction DR1 and the second direction DR2 may be θ. The θ may be greater than approximately 0° and less than approximately 180°. As the θ approaches approximately 0°, each of the first carbon fibers 210 and the second carbon fibers 310 may become relatively parallel to the folding axis Faxis. In other words, as the θ approaches approximately 0°, each of the first carbon fibers 210 and the second carbon fibers 310 may become relatively parallel to the short sides of the first and second support parts 200 and 300, respectively. As the θ approaches approximately 180°, each of the first carbon fibers 210 and the second carbon fibers 310 may become relatively perpendicular to the folding axis Faxis. In other words, as the θ approaches approximately 180°, each of the first carbon fibers 210 and the second carbon fibers 310 may become relatively parallel to the long sides of the first and second support parts 200 and 300, respectively.

In an embodiment of the present invention, the θ may be approximately 90°. In this case, tensile strength of the first carbon fibers 210 in a direction parallel to the folding axis Faxis may be substantially the same as tensile strength of the first carbon fibers 210 in a direction perpendicular to the folding axis Faxis. In addition, tensile strength of the second carbon fibers 310 in the direction parallel to the folding axis Faxis may be substantially the same as tensile strength of the second carbon fibers 310 in the direction perpendicular to the folding axis Faxis. Accordingly, durability of the first and second support parts 200 and 300 with respect to repetitive folding and unfolding of the foldable display device 1000 may be relatively increased.

FIG. 8 is a plan view showing a foldable display device according to an embodiment of the present invention. FIG. 9 is a perspective view showing support parts included in the foldable display device of FIG. 8.

Referring to FIGS. 8 and 9, the first direction DR1 and the second direction DR2 may be perpendicular to each other, and the first direction DR1 may be perpendicular to the folding axis Faxis. For example, each of the first carbon fibers 210 may extend in the direction perpendicular to the folding axis Faxis. In other words, individual first carbon fibers 210 may extend in the first direction DR1. In this case, the first carbon fibers 210 may be arranged in the direction parallel to the folding axis Faxis. In other words, a plurality of the first carbon fibers 210 may be arranged in the second direction DR2. Each of the second carbon fibers 310 may extend in the direction parallel to the folding axis Faxis. In this case, the second carbon fibers 310 may be arranged in the direction perpendicular to the folding axis Faxis.

The tensile strength of the first carbon fibers 210 in the direction perpendicular to the folding axis Faxis may be greater than the tensile strength of the first carbon fibers 210 in the direction parallel to the folding axis Faxis. In other words, the tensile strength of the first carbon fiber 210 in an extension direction DR1 of the first carbon fiber 210 may be relatively great.

The tensile strength of the second carbon fibers 310 in the direction parallel to the folding axis Faxis may be greater than the tensile strength of the second carbon fibers 310 in the direction perpendicular to the folding axis Faxis. In other words, the tensile strength of the second carbon fiber 310 in an extension direction DR2 of the second carbon fiber 310 may be relatively great.

The tensile strength of the first carbon fibers 210 in the direction perpendicular to the folding axis Faxis may be substantially the same as the tensile strength of the second carbon fibers 310 in the direction parallel to the folding axis Faxis. In addition, the tensile strength of the first carbon fibers 210 in the direction parallel to the folding axis Faxis may be substantially the same as the tensile strength of the second carbon fibers 310 in the direction perpendicular to the folding axis Faxis.

As described above, the first direction DR1 may be perpendicular to the folding axis Faxis, and the first direction DR1 and the second direction DR2 may be perpendicular to each other. Accordingly, the durability of the first and second support parts 200 and 300 with respect to the repetitive folding and unfolding of the foldable display device 1000 may be relatively increased.

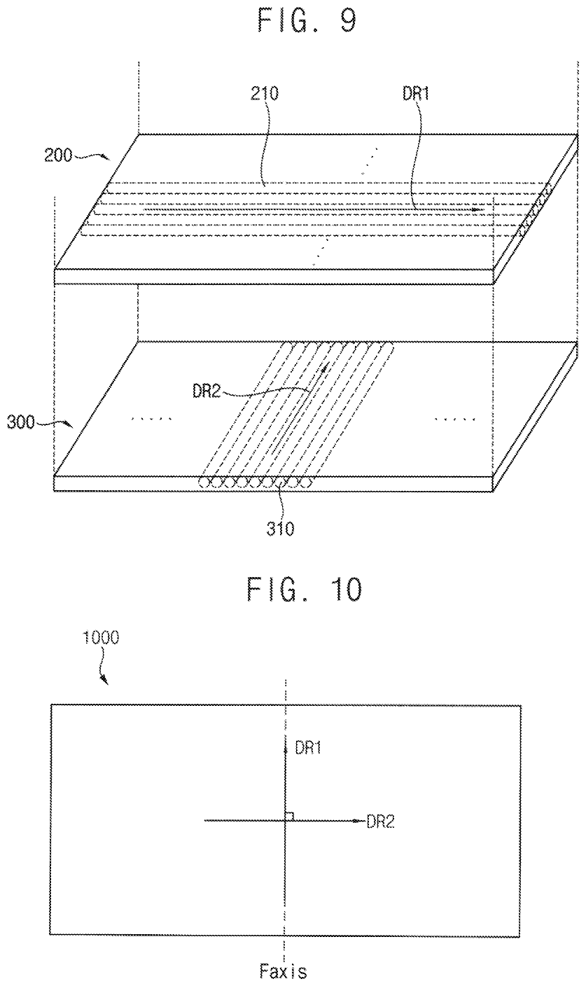

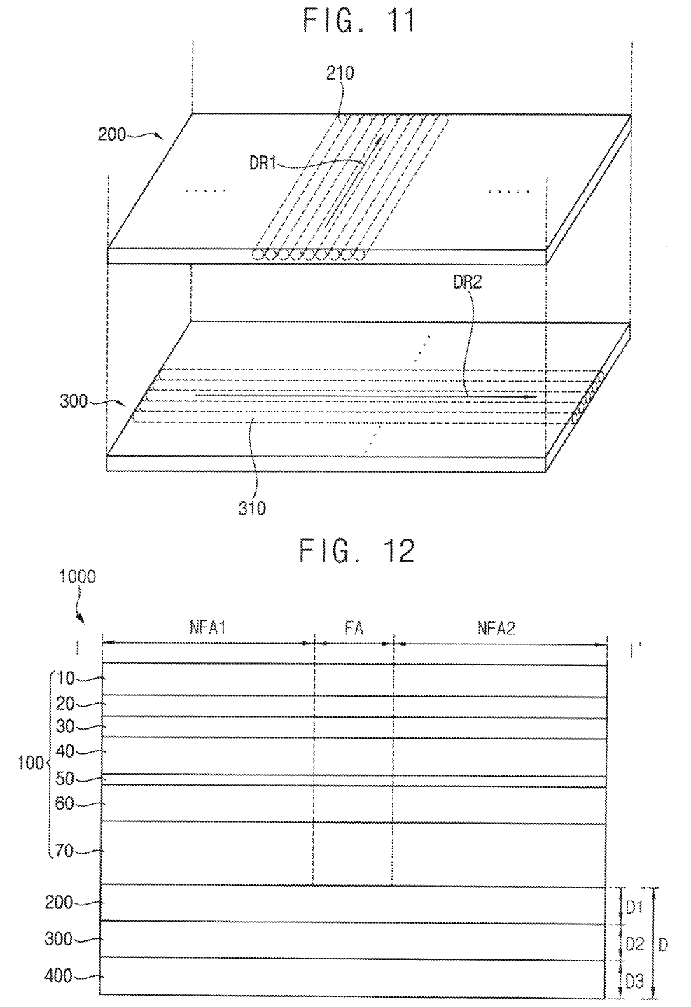

FIG. 10 is a plan view showing a foldable display device according to an embodiment of the present invention. FIG. 11 is a perspective view showing support parts included in the foldable display device of FIG. 10.

Referring to FIGS. 10 and 11, the first direction DR1 and the second direction DR2 may be perpendicular to each other, and the first direction DR1 may be parallel to the folding axis Faxis. For example, each of the first carbon fibers 210 may extend in the direction parallel to the folding axis Faxis. For example, an individual first carbon fiber 210 may extend in the first direction DR1. In other words, the first carbon fibers 210 may be arranged in the direction perpendicular to the folding axis Faxis. For example, a plurality of the first carbon fibers 210 may be arranged in the second direction DR2. Each of the second carbon fibers 310 may extend in the direction perpendicular to the folding axis Faxis. In other words, the second carbon fibers 310 may be arranged in the direction parallel to the folding axis Faxis.

The tensile strength of the first carbon fibers 210 in the direction parallel to the folding axis Faxis may be greater than the tensile strength of the first carbon fibers 210 in the direction perpendicular to the folding axis Faxis. In other words, the tensile strength of the first carbon fiber 210 in the extension direction DR1 may be relatively great.

The tensile strength of the second carbon fibers 310 in the direction perpendicular to the folding axis Faxis may be greater than the tensile strength of the second carbon fibers 310 in the direction parallel to the folding axis Faxis. In other words, the tensile strength of the second carbon fiber 310 in the extension direction DR2 may be relatively great.

The tensile strength of the first carbon fibers 210 in the direction parallel to the folding axis Faxis may be substantially the same as the tensile strength of the second carbon fibers 310 in the direction perpendicular to the folding axis Faxis. In addition, the tensile strength of the first carbon fibers 210 in the direction perpendicular to the folding axis Faxis may be substantially the same as the tensile strength of the second carbon fibers 310 in the direction parallel to the folding axis Faxis.

As described above, the first direction DR1 may be parallel to the folding axis Faxis, and the first direction DR1 and the second direction DR2 may be perpendicular to each other. Accordingly, the durability of the first and second support parts 200 and 300 with respect to the repetitive folding and unfolding of the foldable display device 1000 may be relatively increased.

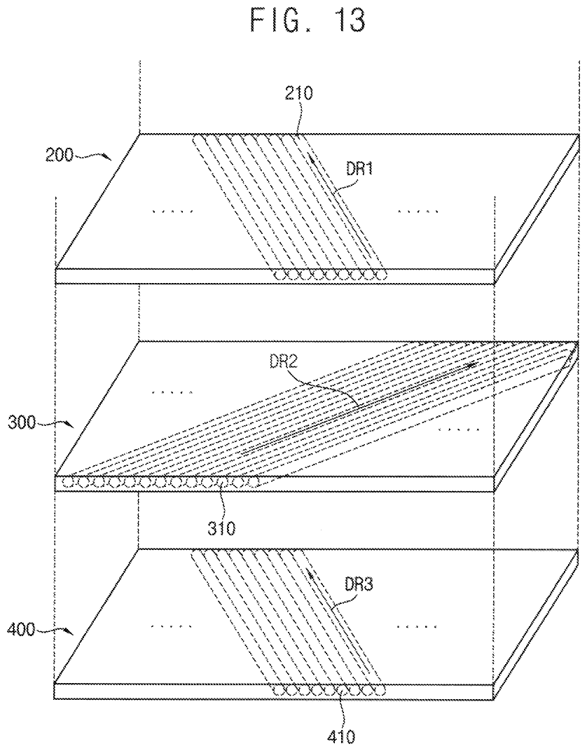

FIG. 12 is a sectional view showing a foldable display device according to an embodiment of the present invention. FIG. 13 is a perspective view showing support parts included in the foldable display device of FIG. 12.

Referring to FIGS. 12 and 13, a first support part 200 may be disposed on a bottom surface of the flexible display module 100. The first support part 200 may support the flexible display module 100. The first support part 200 may include a plurality of first carbon fibers 210 extending in a first direction DR1. For example, the first carbon fibers 210 may extend in a diagonal direction between long sides of the first support part 200.

A second support part 300 may be disposed on a bottom surface of the first support part 200. The second support part 300 may support the flexible display module 100. The second support part 300 may include a plurality of second carbon fibers 310 extending in a second direction DR2. For example, the second carbon fibers 310 may extend in a diagonal direction between long sides of the second support part 300. The first direction DR1 and the second direction DR2 may be different from each other.

A third support part 400 may be disposed on a bottom surface of the second support part 300. For example, the third support part 400 may be in direct contact with the second support part 300. The third support part 400 may completely cover the second support part 300. The third support part 400 may support the flexible display module 100. The third support part 400 may include a plurality of third carbon fibers 410 extending in a third direction DR3.

In an embodiment of the present invention, the third direction DR3 may be substantially identical to the first direction DR1. When the third direction DR3 is substantially identical to the first direction DR1, the carbon fibers 210, 310, and 410 included in the support parts 200, 300, and 400 may not be lifted. In this case, as described above with reference to FIGS. 6 and 7, the first direction DR1 and the second direction DR2 may be symmetrical with each other based on the folding axis Faxis. Alternatively, as described above with reference to FIGS. 8 to 11, the first direction DR1 and the second direction DR2 may be perpendicular to each other. In addition, the first direction DR1 and the second direction DR2 may be symmetrical with each other based on the folding axis Faxis, and the first direction DR1 and the second direction DR2 may be perpendicular to each other.

The first support part 200 may have a first thickness D1, the second support part 300 may have a second thickness D2, and the third support part 400 may have a third thickness D3. In an embodiment of the present invention, a sum D of the first thickness D1, the second thickness D2, and the third thickness D3 may be approximately 80 μm or more and approximately 200 μm or less.

According to the foldable display device 1000 of an embodiment of the present invention, the first support part 200 may include the first carbon fibers 210 extending in the first direction DR1, the second support part 300 may include the second carbon fibers 310 extending in the second direction DR2 that is different from the first direction DR1, and the third support part 400 may include the third carbon fibers 410 extending in the third direction DR3. Accordingly, the first to third support parts 200, 300, and 400 have rigidity that is higher than rigidity of a metal support part having a thickness equal to the sum of the first thickness D1, the second thickness D2, and the third thickness D3. In addition, the first to third support parts 200, 300, and 400 may have a weight that is lower than a weight of the metal support part. Since the first to third support parts 200, 300, and 400 include the first to third carbon fibers 210, 310, and 410, respectively, the first to third support parts 200, 300, and 400 may have a black color. Therefore, the first to third support parts 200, 300, and 400 may not be visually recognized by the user who uses the foldable display device 1000. In addition, since the first to third support parts 200, 300, and 400 include the first to third carbon fibers 210, 310, and 410, respectively, even when the foldable display device 1000 is repeatedly folded and unfolded, creases may not be formed on the first to third support parts 200, 300, and 400.

In an embodiment of the present invention, each of the first support part 200, the second support part 300, and the third support part 400 may include carbon fiber-reinforced plastic (CFRP).

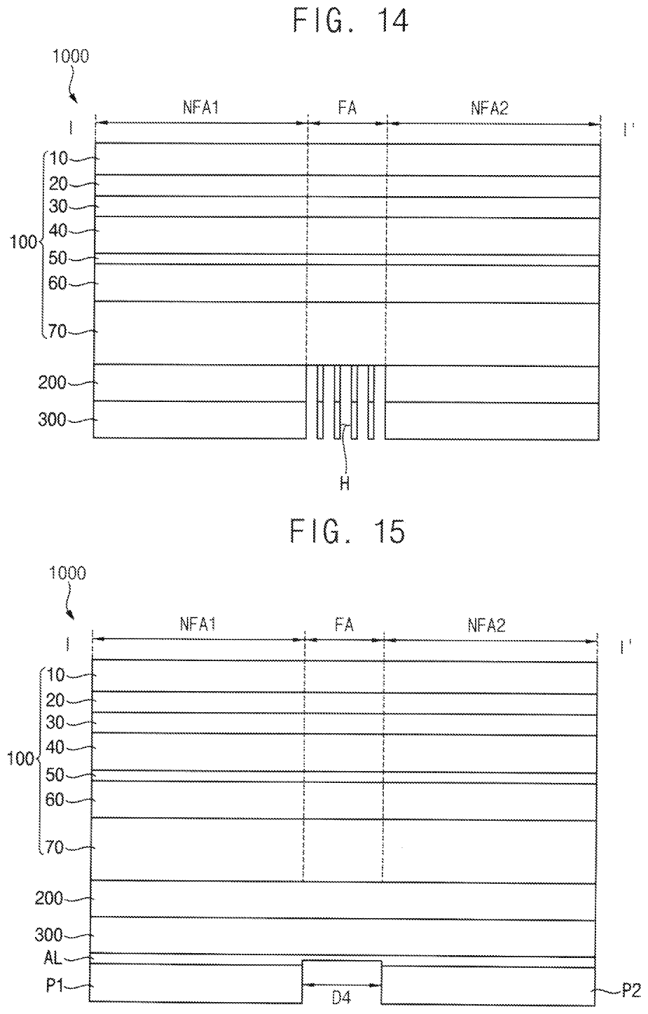

FIG. 14 is a sectional view showing a foldable display device according to an embodiment of the present invention.

Referring to FIG. 14, each of the first support part 200 and the second support part 300 may include a plurality of grooves H formed in the foldable area FA. The groove H may be formed through the first support part 200 and the second support part 300. In an embodiment of the present invention, when the foldable display device 1000 further includes a third support part 400 disposed on a bottom surface of the second support part 300, the foldable display device 1000 may include a plurality of grooves H overlapping the foldable area FA of the flexible display module 100 and formed through the first support part 200, the second support part 300, and the third support part 400. In other words, the third support part 400 may also include grooves H. According to an embodiment of the present invention, the first and second carbon fibers 210 and 310 included in the first and second support parts 200 and 300 may be processed by using a laser to form the grooves H.

The groove H may have various shapes. In an embodiment of the present invention, the grooves H may extend in the direction parallel to the folding axis Faxis, and may be arranged in the direction perpendicular to the folding axis Faxis. In another embodiment of the present invention, the groove H may have a rhombic shape, and one of two diagonal lines of the rhombic shape may be parallel to the folding axis Faxis.

Since the grooves H are formed in the first and second support parts 200 and 300, a repulsive force against the repetitive folding and unfolding of the foldable display device 1000 may be reduced at a portion where the first support part 200 and the foldable area FA overlap each other.

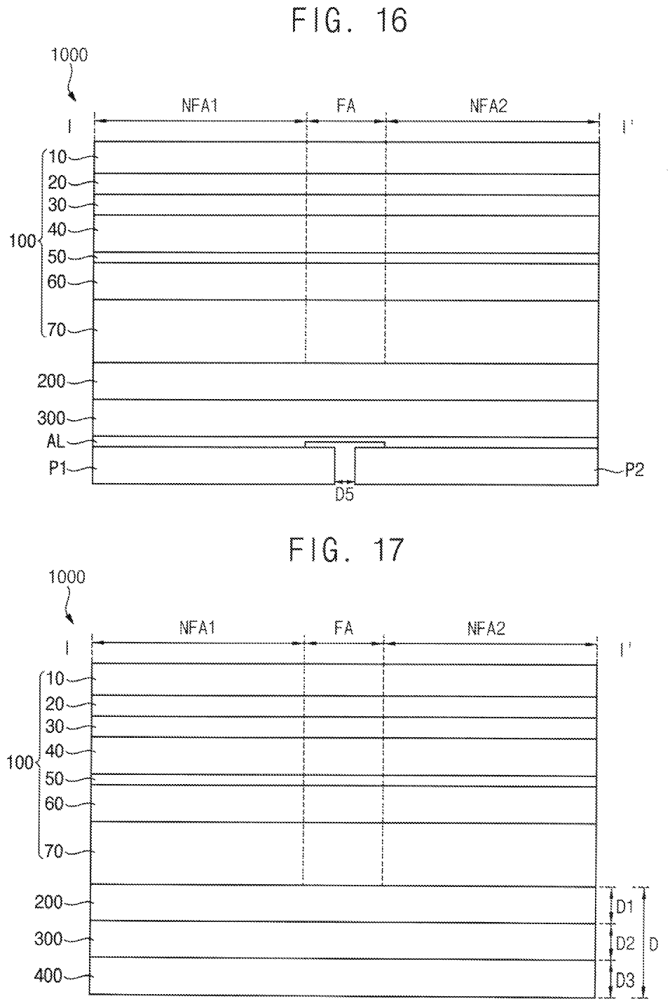

FIGS. 15 and 16 are sectional views showing foldable display devices according to embodiments of the present invention. A redundant description about configurations shown in FIG. 3 will be omitted.

Referring to FIG. 15, the foldable display device 1000 may include a first plate P1 disposed on the bottom surface of the second support part 300 and overlapping the first area NFA1, and a second plate P2 disposed on the bottom surface of the second support part 300 and overlapping the second area NFA2. The first plate P1 and the second plate P2 may be spaced apart from each other by a predetermined distance D4. The predetermined distance D4 may correspond to a width of the foldable area FA between the first and second areas NFA1 and NFA2.

An adhesive layer AL may be disposed between the second support part 300 and the first and second plates P1 and P2. A thickness of a portion of the adhesive layer AL that overlaps the first area NFA1 may be substantially the same as a thickness of a portion of the adhesive layer AL that overlaps the second area NFA2. In an embodiment of the present invention, a thickness of a portion of the adhesive layer AL that overlaps the foldable area FA may be less than the thickness of the portion of the adhesive layer AL that overlaps the first area NFA1. Accordingly, the flexible characteristic of the foldable display device 1000 may be relatively increased.

Referring to FIG. 16, the foldable display device 1000 may include a first plate P1 disposed on the bottom surface of the second support part 300, overlapping the first area NFA1, and partially overlapping the foldable area FA, and a second plate P2 disposed on the bottom surface of the second support part 300, overlapping the second area NFA2, and partially overlapping the foldable area FA. The first plate P1 and the second plate P2 may be spaced apart from each other by a predetermined distance D5. The predetermined distance D5 may be less than the predetermined distance D4.

The adhesive layer AL may be disposed between the second support part 300 and the first and second plates P1 and P2. The thickness of the portion of the adhesive layer AL that overlaps the first area NFA1 may be substantially the same as the thickness of the portion of the adhesive layer AL that overlaps the second area NFA2. In an embodiment of the present invention, the thickness of the portion of the adhesive layer AL that overlaps the foldable area FA may be less than the thickness of the portion of the adhesive layer AL that overlaps the first area NFA1.

Referring to FIGS. 15 and 16, the first and second plates P1 and P2 may support the first and second support parts 200 and 300 and the flexible display module 100. For example, the first and second plates P1 and P2 may prevent the first and second support parts 200 and 300 and the flexible display module 100 from being deformed by the repetitive folding and unfolding of the foldable display device 1000. In addition, the first and second plates P1 and P2 may prevent the first and second support parts 200 and 300 and the flexible display module 100 from being deformed by an external force such as a touch of the user.

Each of the first and second plates P1 and P2 may include a metal material. In an embodiment of the present invention, each of the first and second plates P1 and P2 may include carbon fiber-reinforced plastic (CFRP). The CFRP may include a plurality of carbon fibers extending in one direction, and a binding polymer configured to fix the carbon fibers. When each of the first and second plates P1 and P2 includes the CFRP, a weight of the first and second plates P1 and P2 may be relatively decreased, and rigidity of the first and second plates P1 and P2 may be relatively increased.

In an embodiment of the present invention, the foldable display device 1000 may further include a plurality of grooves overlapping the foldable area FA of the flexible display module 100 and formed through the first support part 200 and the second support part 300. In this case, a repulsive force against the repetitive folding and unfolding of the foldable display device 1000 may be reduced at a portion where the first support part 200 and the foldable area FA overlap each other.

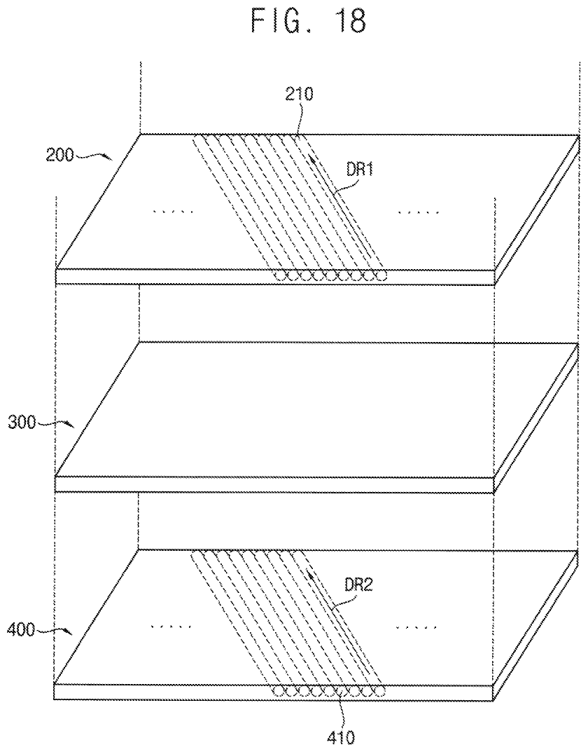

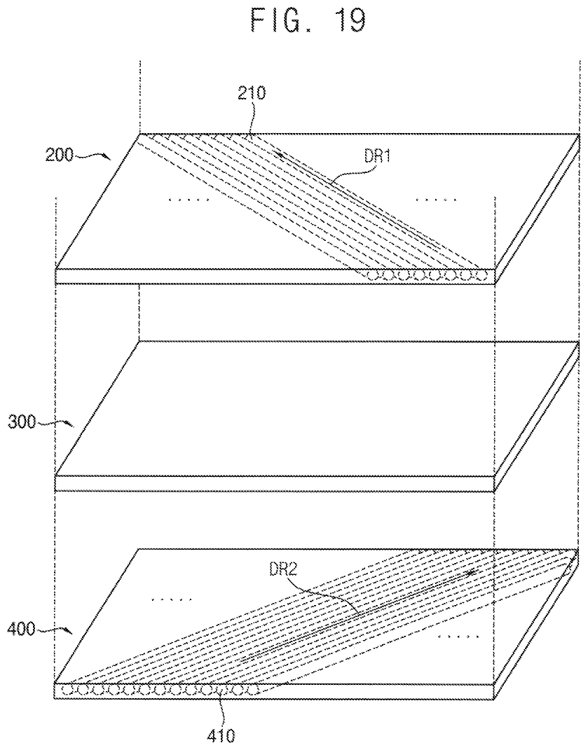

FIG. 17 is a sectional view showing a foldable display device according to an embodiment of the present invention. FIGS. 18 and 19 are perspective views showing support parts included in the foldable display device of FIG. 17.

Referring to FIGS. 17 to 19, the foldable display device 1000 may include a flexible display module 100, a first support part 200, a second support part 300, and a third support part 400. The flexible display module 100 may include a window protection layer 10, a window 20, a polarizing layer 30, a sensing layer 40, a display panel 50, a protective film 60, and a buffer member 70. The flexible display module 100 may be substantially the same as the flexible display module described with reference to FIGS. 1 to 3. For example, the flexible display module 100 shown in FIG. 17 may correspond to a sectional view showing the flexible display module 100 of FIG. 1 taken along line I-I′.

The first support part 200 may be disposed on a bottom surface of the flexible display module 100, and may include a plurality of first carbon fibers 210 extending in a first direction DR1. The second support part 300 may be disposed on a bottom surface of the first support part 200. The second support part 300 may not include carbon fibers. For example, the second support part 300 may include plastic. The third support part 400 may be disposed on a bottom surface of the second support part 300, and may include a plurality of second carbon fibers 410 extending in a second direction DR2. As can be seen, the second support part 300 is sandwiched between the first and third support parts 100 and 300.

Referring to FIGS. 17 and 18, the first direction DR1 may be identical to the second direction DR2. In other words, a direction in which the first carbon fibers 210 extend in the first support part 200 may be substantially identical to a direction in which the second carbon fibers 410 extend in the third support part 400.

Referring to FIGS. 17 and 19, the first direction DR1 may be different from the second direction DR2. In other words, the direction in which the first carbon fibers 210 extend in the first support part 200 may be different from the direction in which the second carbon fibers 410 extend in the third support part 400. In an embodiment of the present invention, the first direction DR1 and the second direction DR2 may be symmetrical with each other based on the folding axis (Faxis of FIG. 1). In another embodiment of the present invention, the first direction DR1 and the second direction DR2 may be perpendicular to each other.

The foldable display device according to the embodiments of the present invention may be applied to a display device included in a laptop computer, a mobile phone, a smartphone, a smart pad, a PMP, a PDA, and the like.

Although the foldable display device according to the embodiments of the present invention have been described with reference to the drawings, the illustrated embodiments are examples, and may be modified and changed by a person having ordinary knowledge in the relevant technical field without departing from the scope of the present invention.

What is claimed is:

1. A foldable display device, comprising:
a flexible display module including a first area, a second area, and a foldable area between the first area and the second area;
a first support part disposed under the flexible display module, and including a plurality of first carbon fibers extending in a first direction; and
a second support part disposed under the first support part, and including a plurality of second carbon fibers extending in a second direction.

2. The foldable display device of claim 1, wherein the first direction and the second direction are different from each other.

3. The foldable display device of claim 1, wherein the flexible display module is foldable along a folding axis in the folding area, and
the first direction and the second direction are symmetrical to each other based on the folding axis.

4. The foldable display device of claim 1, wherein the flexible display module is foldable along a folding axis in the folding area, and
the first direction and the second direction are perpendicular to each other.

5. The foldable display device of claim 4, wherein the first direction is parallel to the folding axis.

6. The foldable display device of claim 4, wherein the first direction is perpendicular to the folding axis.

7. The foldable display device of claim 1, further comprising a third support part disposed under the second support part, and including a plurality of third carbon fibers extending in a third direction.

8. The foldable display device of claim 7, wherein the third direction is identical to the first direction.

9. The foldable display device of claim 8, wherein the flexible display module is foldable about a folding axis in the folding area,
the first direction and the second direction are symmetrical with each other based on the folding axis, and
the first direction and the second direction are perpendicular to each other.

10. The foldable display device of claim 1, wherein each of the first support part and the second support part includes carbon fiber-reinforced plastic (CFRP).

11. The foldable display device of claim 1, wherein each of the first support part and the second support part further includes a plurality of grooves in the foldable area.

12. The foldable display device of claim 1, further comprising:
a first plate disposed under the second support part, and overlapping the first area; and
a second plate disposed under the second support part, overlapping the second area, and spaced apart from the first plate.

13. The foldable display device of claim 12, wherein each of the first plate and the second plate partially overlaps the foldable area.

14. The foldable display device of claim 12, wherein each of the first plate and the second plate includes carbon fiber-reinforced plastic (CFRP).

15. A foldable display device, comprising:
a flexible display module including a first area, a second area, and a foldable area between the first area and the second area;
a first support part disposed under the flexible display module, and including a plurality of first carbon fibers extending in a first direction;
a second support part disposed under the first support part; and
a third support part disposed under the second support part, and including a plurality of second carbon fibers extending in a second direction.

16. The foldable display device of claim 15, wherein the first direction is identical to the second direction.

17. The foldable display device of claim 15, wherein the first direction is different from the second direction.

18. The foldable display device of claim 17, wherein the flexible display module is foldable about a folding axis in the folding area, and
the first direction and the second direction are symmetrical with each other based on the folding axis.

19. The foldable display device of claim 17, wherein the first direction and the second direction are perpendicular to each other.

20. The foldable display device of claim 15, wherein the second support part does not include carbon fibers.

21. A foldable display device, comprising:
a flexible display module including a first area, a second area, and a foldable area between the first area and the second area;
a first support part disposed under the flexible display module; and
a second support part disposed under the first support part, wherein at least one of the first support part and the second support part includes carbon fibers.

22. The foldable display device of claim 21, wherein at least one of the first support part and the second support part includes a groove in the folding area.

23. The foldable display device of claim 21, further comprising a first plate disposed on the second support part in the first area and a second plate disposed on the second support part in the second area, wherein the first plate and the second plate are separated from each other in the folding area.
